(19) United States
(12) Patent Application Publication
(10) Pub. No.: US 2015/0263065 A1
(43) Pub. Date: Sep. 17, 2015

(54) LIGHT EMITTING DEVICE AND METHOD OF MANUFACTURING THE SAME

(71) Applicant: KABUSHIKI KAISHA TOSHIBA, Tokyo (JP)

(72) Inventors: Kazuhiro INOUE, Komatsu Ishikawa (JP); Masahiro OGUSHI, Nonoichi Ishikawa (JP); Hidenori EGOSHI, Nonoichi Ishikawa (JP)

(21) Appl. No.: 14/475,505

(22) Filed: Sep. 2, 2014

(30) Foreign Application Priority Data
Mar. 14, 2014 (JP) 2014-052671

(51) Int. Cl. H01L 27/15; H01L 33/00; H01L 33/56; H01L 33/50; H01L 33/60; H01L 33/58

(52) U.S. Cl. CPC H01L 27/15; H01L 33/60; H01L 33/58; H01L 33/56; H01L 33/50; H01L 33/005

(57) ABSTRACT

A light emitting device includes a first light emitting element on a substrate and a second light emitting element spaced from the first light emitting. A resin body is disposed between the first and second light emitting elements so as to surround the first and second light emitting elements in a plane parallel to the substrate. The resin body has a thickness in a direction orthogonal to the substrate that is greater than a thickness of each of the first and second light emitting elements. A translucent resin element is disposed on the resin body and the first and second light emitting elements. The resin body and the first and second light emitting elements are between the translucent resin element and the substrate in the first direction.

### CROSS-REFERENCE TO RELATED APPLICATION

This application is based upon and claims the benefit of priority from Japanese Patent Application No. 2014-052671, filed Mar. 14, 2014, the entire contents of which are incorporated herein by reference.

### FIELD

Embodiments described herein relate generally to a light emitting device and a method of manufacturing the same.

### BACKGROUND

Examples of semiconductor light emitting elements include light emitting diodes (LED) and semiconductor laser diodes. Light emitting devices combining semiconductor light emitting elements and fluorescent substances are used, for example, in displays and illumination devices. These light emitting devices are required to have high luminous efficiency.

### DESCRIPTION OF THE DRAWINGS

FIGS. 1A and 1B are views schematically illustrating a light emitting device according to a first embodiment.

FIG. 2 is a cross-sectional view schematically illustrating another light emitting device according to the first embodiment.

FIG. 3 is a cross-sectional view schematically illustrating another light emitting device according to the first embodiment.

FIGS. 4A to 4E are cross-sectional views schematically illustrating a process of manufacturing a light emitting device according to the first embodiment.

FIGS. 5A and 5B are perspective views schematically illustrating the process of manufacturing the light emitting device according to the first embodiment.

### DETAILED DESCRIPTION

Embodiments provide a light emitting device having high luminous efficiency, and a method of manufacturing the light emitting device.

According to an embodiment, a light emitting device includes a first light emitting element on a substrate and a second light emitting element on the substrate and spaced from the first light emitting. A resin body is disposed between the first and second light emitting elements so as to surround the first and second light emitting elements in a plane parallel to the substrate. The resin body has a thickness in a first direction orthogonal to the substrate (e.g., Z-direction) that is greater than a thickness in the first direction of each of the first and second light emitting elements. A translucent resin element is disposed on the resin body and the first and second light emitting elements. The resin body and the first and second light emitting elements are between the translucent resin element and the substrate in the first direction. In some embodiments, the translucent resin element may be shaped as a lens element or a plurality of lens elements.

In general, according to one embodiment, a light emitting device that includes a substrate, a first translucent portion, a resin body, a first semiconductor light emitting element, and a second semiconductor light emitting element is provided. The first translucent portion is provided on the substrate and has translucency. The resin body is provided between the substrate and the first translucent portion, and is reflective, and includes a first portion, a second portion, and a third portion. The first portion is in contact with the first translucent portion. The second portion is separated from the first portion in a second direction intersecting with a first direction from the substrate toward the first translucent portion, and is in contact with the first translucent portion. The third portion is provided between the first portion and the second portion so as to be separated from the first portion and the second portion in the second direction and to be in contact with the first translucent portion. The first semiconductor light emitting element is provided between the substrate and the first translucent portion so as to be disposed between the first portion and the third portion. The second semiconductor light emitting element is provided between the substrate and the first translucent portion so as to be disposed between the second portion and the third portion.

Hereinafter, each embodiment will be described with reference to the accompanying drawings. Also, the drawings are schematic or conceptual, and the relation between the thickness and width of each portion, the size ratio of portions, and the like are not necessarily the same as those in reality. Further, identical portions may be shown with different dimensions or ratios depending on the drawings.

Also, in this disclosure and the drawings, components substantially similar to those described in regard to one drawing are marked with the same reference numerals in other drawings, and a detailed description may be omitted as appropriate for repeated elements.

### FIRST EMBODIMENT

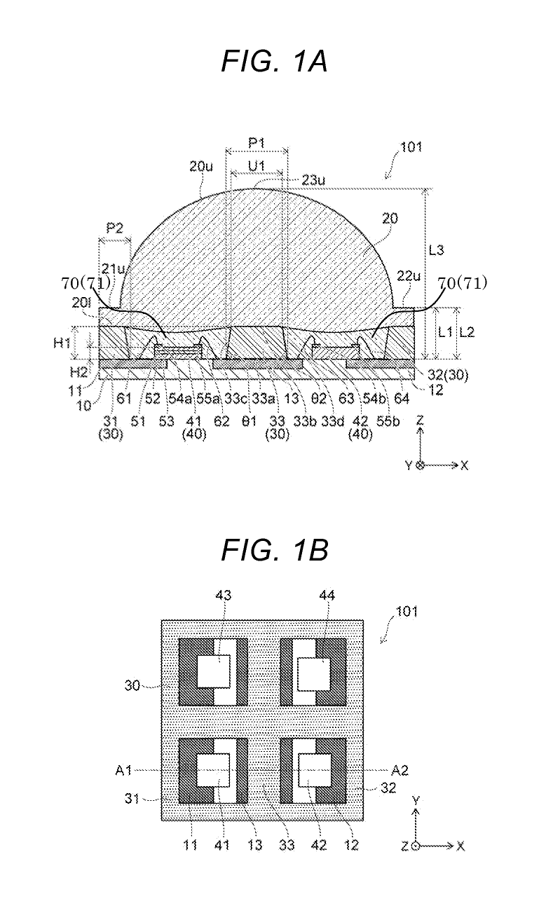

FIGS. 1A and 1B are views schematically illustrating a light emitting device according to a first embodiment.

FIG. 1A is a cross-sectional view schematically illustrating a light emitting device 101.

FIG. 1B is a plan view schematically illustrating the light emitting device 101. FIG. 1A illustrates a cross section taken along a line A1-A2 of FIG. 1B.

As shown in FIGS. 1A and 1B, the light emitting device 101 includes a substrate 10, a first translucent portion 20, a resin body 30 (a resin molded body), a first semiconductor light emitting element 41, and a second semiconductor light emitting element 42.

The substrate 10 is a lead frame for the light emitting device. The substrate 10 maybe formed of at least one of copper (Cu), an alloy containing copper, and an alloy of iron (Fe) and nickel (Ni). Alternatively, the substrate 10 maybe formed of a resin or ceramic. In a case where the substrate 10 is formed of a resin or ceramic, conductive portions (wiring lines) (to be described below) are provided in the substrate 10. The conductive portions may be formed of copper (Cu) or iron (Fe), or the like.

The first translucent portion 20 is provided on the substrate 10. The first translucent portion 20 has translucency with respect to light emitted by the light emitting elements 41, 42. The first translucent portion 20 may be formed of a silicon resin or an epoxy resin. The first translucent portion 20 is, for example, shaped as a lens of the light emitting device.

A direction from the substrate 10 toward the first translucent portion 20 is defined as a Z-axis direction. Also, a direction perpendicular to the Z-axis direction is defined as an X-axis direction. Further, a direction perpendicular to both of the X-axis direction and the Z-axis direction is defined as a Y-axis direction.

Between the substrate 10 and the first translucent portion 20, the resin body 30 is provided. The resin body 30 includes a first portion 31, a second portion 32, and a third portion 33. The resin body 30 may be formed of a white resin, for example. The resin body 30 may be reflective.

Each of the first portion 31, the second portion 32, and the third portion 33 is in contact with the first translucent portion 20. For example, each of the first portion 31, the second portion 32, and the third portion 33 is in contact with the substrate 10.

The second portion 32 is separated from the first portion 31 in a direction (a second direction) intersecting with the Z-axis direction (a first direction). In this example, the second direction is the X-axis direction.

The third portion 33 is separated from the first portion 31 and the second portion 32 in the second direction (in this example, the X-axis direction). The third portion 33 is provided between the first portion 31 and the second portion 32.

The light emitting device 101 includes a plurality of semiconductor light emitting elements 40 (the first semiconductor light emitting element 41 and the second semiconductor light emitting element 42).

The first semiconductor light emitting element 41 is provided on the substrate 10. The first semiconductor light emitting element 41 is between the first portion 31 and the third portion 33 and between the first translucent portion 20 and the substrate 10.

The second semiconductor light emitting element 42 is provided on the substrate 10. The second semiconductor light emitting element 42 is between the second portion 32 and the third portion 33 and between the first translucent portion 20 and the substrate 10.

In this example, the light emitting device 101 further includes a third semiconductor light emitting element 43 and a fourth semiconductor light emitting element 44 (see FIG. 1B). Each of the third semiconductor light emitting element 43 and the fourth semiconductor light emitting element 44 is also provided on the substrate 10. Each of the third semiconductor light emitting element 43 and the fourth semiconductor light emitting element 44 is also provided between the first translucent portion 20 and the substrate 10.

The third semiconductor light emitting element 43 is separated from the first semiconductor light emitting element 41 in a third direction (in this example, the Y-axis direction) intersecting with the first direction and the second direction. The fourth semiconductor light emitting element 44 is separated from the second semiconductor light emitting element 42 in the third direction (for example, the Y-axis direction). The third semiconductor light emitting element 43 is separated from the fourth semiconductor light emitting element 44 in the second direction.

That is, in this example, the semiconductor light emitting elements are disposed in a two-by-two matrix in an X-Y plane. As described above, the light emitting device 101 includes four semiconductor light emitting elements. However, the number of semiconductor light emitting elements to be included in a light emitting device according to the present disclosure can be changed. For example, semiconductor light emitting elements may be disposed in a three-by-three matrix in the X-Y plane. In this case, a light emitting device includes nine semiconductor light emitting elements.

It is preferable that the number of semiconductor light emitting elements which forms a line in the X-axis direction should be equal to the number of semiconductor light emitting elements which forms a line in the Y-axis direction. For example, it is preferable that the length of the light emitting device 101 in the X-axis direction should be substantially equal to the length of the light emitting device 101 in the Y-axis direction. In this case, it becomes easier to manufacture light emitting devices, for example, in a manufacturing process to be described below, and it is possible to reduce the manufacturing cost.

The semiconductor light emitting elements 40 are, for example, light emitting diode (LED) chips. The semiconductor light emitting elements 40 are, for example, LEDs using a GaN-based nitride semiconductor as a material. For example, each semiconductor light emitting element 40 includes an n-type semiconductor layer 51 (for example, an n-type GaN layer), a light emitting layer 52 (a semiconductor light emitting layer), and a p-type semiconductor layer 53 (for example, a p-type GaN layer). Between the n-type semiconductor layer 51 and the substrate 10, the p-type semiconductor layer 53 is disposed. Between the n-type semiconductor layer 51 and the p-type semiconductor layer 53, the light emitting layer 52 is disposed. The light emitting layer 52 may be a semiconductor layer which is formed of a nitride semiconductor or the like. The light emitting layer 52 has, for example, a multiple quantum well structure.

Each semiconductor light emitting element 40 further includes a cathode (an electrode) 55, which is electrically connected to the n-type semiconductor layer 51, and an anode (an electrode) 54, which is electrically connected to the p-type semiconductor layer 53. If electric power is applied to the light emitting layer 52 through the anode 54 and the cathode 55, the light emitting layer 52 emits light.

The first semiconductor light emitting element 41 includes a first anode 54a and a first cathode 55a. The second semiconductor light emitting element 42 includes a second anode 54b and a second cathode 55b, etc.

In this example, the anodes 54 and the cathodes 55 are provided on the upper surfaces of the semiconductor light emitting elements 40 (surfaces facing the first translucent portion 20). In the embodiment, for example, the anodes 54 may be provided on the lower surfaces of the semiconductor light emitting element 40. That is, each anode 54 may be provided between the p-type semiconductor layer 53 and the substrate 10.

Alternatively, all of the cathodes 55 and the anodes 54 may be provided on the lower surfaces of the semiconductor light emitting elements 40. That is, the semiconductor light emitting elements 40 may be flip-chip LEDs.

In the embodiment, the semiconductor light emitting elements 40 are not limited to LEDs, and may be laser diodes (LDs).

In this example, the first translucent portion 20 is provided as one lens. For example, the first translucent portion 20 has an upper surface 20u and a lower surface 20l. The lower surface 20l is provided between the upper surface 20u and the substrate 10. For example, the upper surface 20u includes a first upper portion 21u, a second upper portion 22u, and a third upper portion 23u.

The first portion 31 is provided between the first upper portion 21u and the substrate 10. The second portion 32 is provided between the second upper portion 22u and the substrate 10. The third portion 33 is provided between the third upper portion 23u and the substrate 10.

A first distance L1 between the substrate 10 and the first upper portion 21u along the Z-axis direction is shorter than a third distance L3 between the substrate 10 and the third upper portion 23u along the Z-axis direction.

A second distance L2 between the substrate 10 and the upper portion 22u along the Z-axis direction is shorter than the third distance L3. That is, the first translucent portion 20 has a lens shape convex at its central portion as the first translucent portion 20 is projected onto an X-Y plane.

In this example, the light emitting device 101 further includes elements 70, which in this embodiment are second translucent portions 70 having translucency at relevant wavelengths. The second translucent portions 70 are provided between the first semiconductor light emitting element 41 and the first translucent portion 20, and between the second semiconductor light emitting element 42 and the first translucent portion 20, respectively. The second translucent portions 70 may be formed of a transparent resin.

In other embodiments, elements 70 include fluorescent material, or are formed of a fluorescent resin, and may be referred to as wavelength conversion layers 71. The wavelength conversion layers 71 are also disposed between the first semiconductor light emitting element 41 and the first translucent portion 20, and between the second semiconductor light emitting element 42 and the first translucent portion 20. For example, the first semiconductor light emitting element 41 emits first light having a first peak wavelength. The wavelength conversion layer 71 absorbs at least a portion of the first light, and emits a second light. The second light has a second peak wavelength different from the first peak wavelength.

Between every two of the semiconductor light emitting elements 40, a portion of the resin body 30 is provided. That is, between the first semiconductor light emitting element 41 and the third semiconductor light emitting element 43, between the second semiconductor light emitting element 42 and the fourth semiconductor light emitting element 44, and between the third semiconductor light emitting element 43 and the fourth semiconductor light emitting element 44, portions of the resin body 30 are provided, respectively.

As described above, in the light emitting device 101, the plurality of semiconductor light emitting elements 40 is integrally provided on the substrate. Therefore, it is possible to obtain a small-sized, high-power light emitting device.

Further, in the light emitting device 101, between every two adjacent semiconductor light emitting elements 40, a portion of the resin body 30 is provided. The resin body 30 surrounds each of the plurality of semiconductor light emitting elements 40. The shape of the resin body 30 is, for example, a reflector shape (e.g., has a face or faces facing the light emitting elements 40 that are outwardly angled from the primary light emission axis). That is, a portion of light emitted from each of the semiconductor light emitting elements 40 is reflected by the resin body 30 toward the first translucent portion 20. Therefore, for example, it is possible to reduce loss of light emitted from each of the semiconductor light emitting elements 40.

As compared to a case where a portion of the resin body 30 is not provided between every two of the semiconductor light emitting elements 40, it is possible to improve luminous efficiency by adopting the configuration of the light emitting device 101 according to the embodiment.

As described above, the shape of the resin body 30 is a reflector shape. As depicted in FIG. 1A, the height of the resin body 30 is set to be higher than the height of the first semiconductor light emitting element 41. That is, the height (a first height H1) of the resin body 30 (for example, the third portion 33) along the Z-axis direction is longer than the height (a second height H2) of the first semiconductor light emitting element 41 along the Z-axis direction.

For example, the third portion 33 has a first surface 33a, a second surface 33b, a first side surface 33c, and a second side surface 33d.

The first surface 33a is a surface facing the substrate 10. That is, the first surface 33a is the lower surface of the third portion 33 as depicted in FIG. 1A.

The second surface 33b is separated from the first surface 33a in the Z-axis direction, and faces the first translucent portion 20. That is, the second surface 33b is the upper surface of the third portion 33 as depicted in FIG. 1A.

The first side surface 33c and the second side surface 33d are provided between the first surface 33a and the second surface 33b. The first side surface 33c and the second side surface 33d intersect with the second direction (for example, the X-axis direction). Between the second side surface 33d and the first portion 31, the first side surface 33c is disposed.

The length of the first surface 33a (first lower surface length P1) along the second direction is longer than the length of the second surface 33b (first upper surface length U1) along the second direction.

A first angle θ1 between the first surface 33a and the first side surface 33c is in a range from 30 degrees to 90 degrees. A second angle θ2 between the first surface 33a and the second side surface 33d is in a range from 0 degree to 120 degrees.

The shape of the resin body provided between every two of the semiconductor light emitting elements 40 is a reflector shape. Therefore, light emitted from the semiconductor light emitting elements 40 is efficiently reflected from the resin body 30 toward the first translucent portion 20. Therefore, it is possible to improve the luminous efficiency of the light emitting device.

The first portion 31 has a third surface 31a. The third surface 31a is a surface facing the substrate 10. That is, the third surface 31a is the lower surface of the first portion 31.

For example, the length of the third surface (a second lower surface length P2) along the second direction (for example, the X-axis direction) is in a range from 0.4 times to 0.6 times of the length of the first surface 33a (the first lower surface length P1) along the second direction. The second lower surface length P2 is, for example, half of the first lower surface length P1.

In this example, the substrate 10 includes a first conductive portion 11, a second conductive portion 12, and a third conductive portion 13. The second conductive portion 12 is separated from the first conductive portion 11 in the second direction. The third conductive portion 13 is separated from the first conductive portion 11 and the second conductive portion 12 in the second direction. For example, the third conductive portion 13 is provided between the first conductive portion 11 and the second conductive portion 12.

At least a portion of the first semiconductor light emitting element 41 is provided between the first conductive portion 11 and the first translucent portion 20. For example, at least a portion of the first portion 31 is provided between the first conductive portion 11 and the first translucent portion 20.

At least a portion of the second semiconductor light emitting element 42 is provided between the second conductive portion 12 and the first translucent portion 20. For example, at least a portion of the second portion 32 is provided between the second conductive portion 12 and the first translucent portion 20.

At least a portion of the third portion 33 is provided between the third conductive portion 13 and the first translucent portion 20.

For example, the first anode 54a of the first semiconductor light emitting element 41 is electrically connected to the first conductive portion 11. For example, the first anode 54a and the first conductive portion 11 are connected by a first wiring line 61.

For example, the first cathode 55a of the first semiconductor light emitting element 41 is electrically connected to the third conductive portion 13. For example, the first cathode 55a and the third conductive portion 13 are connected by a second wiring line 62.

For example, the second anode 54b of the second semiconductor light emitting element 42 is electrically connected to the third conductive portion 13. For example, the second anode 54b and the third conductive portion 13 are connected by a third wiring line 63.

For example, the second cathode 55b of the second semiconductor light emitting element 42 is electrically connected to the second conductive portion 12. For example, the second cathode 55b and the second conductive portion 12 are connected by a fourth wiring line 64. The first to fourth wiring lines 61 to 64 are, for example, bonding wires.

As described above, the first cathode 55a of the first semiconductor light emitting element 41 and the second anode 54b of the second semiconductor light emitting element 42 are electrically connected to each other through the third conductive portion 13. Therefore, for example, it is possible to reduce the lengths of wiring lines to be connected to the electrodes of the first semiconductor light emitting element 41 and the electrodes of the second semiconductor light emitting element 42, respectively, and it is possible to improve luminous efficiency.

For example, the wiring lines which are connected to the electrodes may absorb light emitted from the semiconductor light emitting elements 40. For this reason, in a case where the wiring lines, which are connected to the electrodes, respectively, are long, the luminous efficiency of the light emitting device may be reduced.

In contrast to this, in the light emitting device 101, the third conductive portion 13 is provided below the third portion 33. Through this third conductive portion 13, the first cathode 55a and the second anode 54b are electrically connected to each other. Therefore, it is possible to reduce the lengths of the wiring lines, and it is possible to improve luminous efficiency.

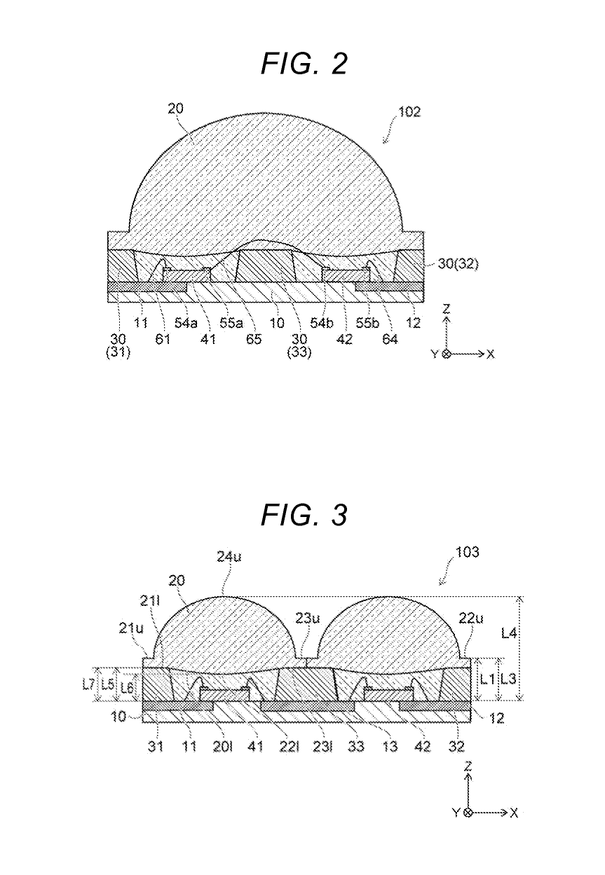

FIG. 2 is a cross-sectional view schematically illustrating another light emitting device according to the first embodiment.

FIG. 2 illustrates a light emitting device 102. The light emitting device 102 also includes a substrate 10, a first translucent portion 20, a resin body 30, a first semiconductor light emitting element 41, a second semiconductor light emitting element 42, and so on. These components may have the same configurations as those described with respect to the light emitting device 101.

In the light emitting device 102, a first cathode 55a and a second anode 54b are electrically connected to each other through a fifth wiring line 65. Like this, the first cathode 55a and the second anode 54b may be connected by a bonding wire.

Since a bonding wire is used as described above, regardless of the pattern of conductive portions (such as a third conductive portion 13) which are provided in the substrate 10, it is possible to connect the semiconductor light emitting elements 40.

In a process of manufacturing a light emitting device according to the embodiment, it is possible to select the number of semiconductor light emitting elements 40 to be provided in the light emitting device. In this example, the semiconductor light emitting elements 40 are connected by bonding wires. Therefore, for example, it is possible to avoid change in the specification of the substrate 10 even when the number of light emitting elements 40 to be included in the final device is varied. It is thus possible to reduce the manufacturing cost of the light emitting devices, and it is possible to improve manufacturing efficiency.

FIG. 3 is a cross-sectional view schematically illustrating another light emitting device according to the first embodiment.

FIG. 3 illustrates a light emitting device 103. The light emitting device 103 also includes a substrate 10, a resin body 30, a first semiconductor light emitting element 41, a second semiconductor light emitting element 42, and so on. These components may have the same configurations as those described with respect to the light emitting device 101.

Similarly to the first translucent portion 20 of the light emitting device 101, a first translucent portion 20 of the light emitting device 103 has an upper surface 20u and a lower surface 20l.

Even in the light emitting device 103, the upper surface 20u has a first upper portion 21u, a second upper portion 22u, and a third upper portion 23u. The upper surface 20u further includes fourth upper portions 24u.

The first portion 31 is provided between the first upper portion 21u and the substrate 10. The third portion 33 is provided between the third upper portion 23u and the substrate 10. The first semiconductor light emitting element 41 is provided between a fourth upper portion 24u and the substrate 10.

In the light emitting device 103, the first distance L1 between the substrate 10 and the first upper portion 21u along the Z-axis direction is shorter than a fourth distance L4 between the substrate 10 and each fourth upper portion 24u along the Z-axis direction.

In the light emitting device 103, the third distance L3 between the substrate 10 and the third upper portion 23u along the Z-axis direction is shorter than the fourth distance L4 between the substrate 10 and each fourth upper portion 24u along the Z-axis direction. As described above, the shape of a portion of the first translucent portion 20 on each of the plurality of semiconductor light emitting elements 40 may be a convex lens shape. That is, a separate lens element may be provided above each light emitting element 40.

For example, as illustrated in the light emitting device 101 and the light emitting device 103, the lens shape can be adjusted for each light emitting element 40 position. By this adjustment, for example, it is possible to adjust the light distribution characteristic of each light emitting device.

In the light emitting devices 101 to 103, the lower surface 20l includes a first lower portion 21l, a second lower portion 22l, and a third lower portion 23l. The first portion 31 is provided between the first lower portion 21l and the substrate 10. The first semiconductor light emitting element 41 is provided between the second lower portion 22l and the substrate 10. The third portion 33 is provided between the third lower portion 23l and the substrate 10.

A fifth distance L5 between the substrate 10 and the first lower portion 21l along the Z-axis direction is longer than a sixth distance L6 between the substrate 10 and the second lower portion 22l along the Z-axis direction. A seventh distance L7 between the substrate 10 and the third lower portion 23l is longer than the sixth distance L6. That is, in the light emitting devices 101 to 103 according to the embodiment, on each of the plurality of semiconductor light emitting elements 40, the first translucent portion 20 has a downwardly convex shape. Therefore, for example, it is possible to adjust the light distribution characteristic of each light emitting device, and it is possible to obtain high luminous efficiency.

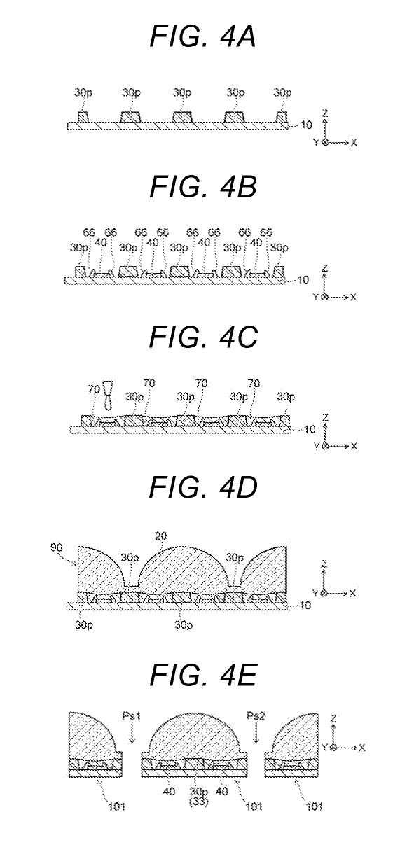

FIGS. 4A to 4E are cross-sectional views schematically illustrating a process of manufacturing a light emitting device according to the first embodiment.

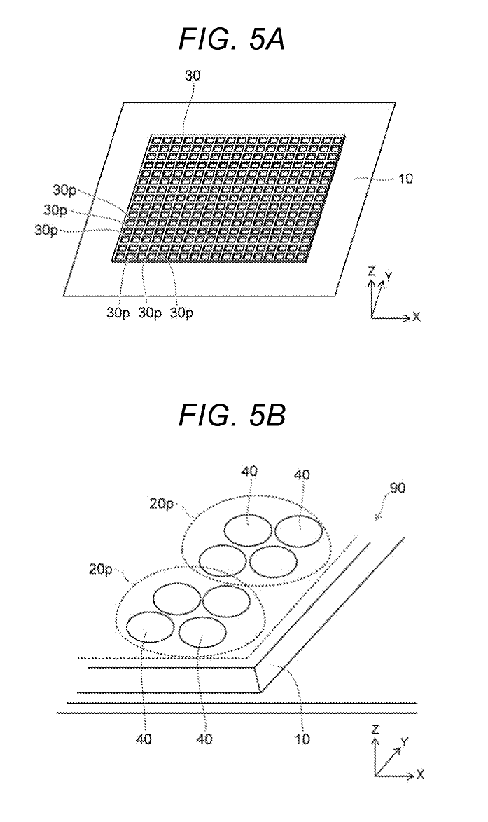

FIGS. 5A and 5B are perspective views schematically illustrating the process of manufacturing the light emitting device according to the first embodiment.

As shown in FIG. 4A, on the substrate 10 (the lead frame), the resin body 30 is formed. The resin body 30 includes, for example, a plurality of sections 30p (molded portions) which are separated from one another in the X-axis direction. The sections 30p include, for example, the first to third portions 31 to 33. FIG. 5A illustrates the resin body 30 formed on the substrate as described above. For example, the resin body 30 further includes a plurality of sections 30p which are separated from one another in the Y-axis direction. For example, the resin body 30 is rectangular shape.

As shown in FIG. 4B, between every neighboring two of the plurality of sections 30p, semiconductor light emitting elements 40 are disposed on the substrate 10. Each of the semiconductor light emitting elements 40 is connected to the substrate 10, for example, by wiring lines 66 (bonding wires).

As shown in FIG. 4C, on each of the plurality of semiconductor light emitting elements 40, a transparent resin precursor material is dispensed, whereby a second translucent portion 70 is formed from the precursor material.

As shown in FIG. 4D, on the resin body 30 and the plurality of semiconductor light emitting elements 40, the first translucent portion 20 is formed. The first translucent portion 20 is formed, for example, by molding. The first translucent portion 20 is in contact with the plurality of sections 30p. In this way, a workpiece 90 is formed. FIG. 5B illustrates the workpiece 90. In this example, the first translucent portion 20 includes a plurality of lens portions 20p which is disposed in the X-Y plane. As depicted in FIG. 5B, between each lens portion 20p and the substrate 10, four semiconductor light emitting elements 40 are disposed.

As shown in FIG. 4E, the workpiece 90 including the substrate 10, the resin body 30, the semiconductor light emitting elements 40, and the translucent portion (the first translucent portion 20) is diced (cut). For dicing, for example, blade dicing can be used.

In the dicing process, the first translucent portion 20, the resin body 30, and the substrate 10 are cut. For example, the workpiece 90 is cut at a plurality of positions including a first position Ps1 and a second position Ps2. For example, along the shapes of the lens portions 20p, dicing can be performed.

The workpiece 90 includes at least one section 30p between the first position Psi and the second position Ps2. In this example, between the first position Ps1 and the second position Ps2, one section 30p is provided.

The workpiece 90 includes a plurality of (at least two) semiconductor light emitting elements 40 between the first position Psi and the second position Ps2. In this example, between the first position Ps1 and the second position Ps2, two semiconductor light emitting elements 40 are provided along the X-direction. In this way, the light emitting device 101 is completed.

The third portion 33 of the light emitting device 101 manufactured as described above has, for example, a seamless shape. Therefore, it is possible to reduce intervals between every two semiconductor light emitting elements 40. It is possible to obtain a light emitting device having high luminous efficiency per area.

As described above, a light emitting device including a plurality of semiconductor light emitting elements 40 and a resin body 30 formed integrally is provided. Therefore, for example, as compared to a device incorporating a plurality of chips each having only one semiconductor light emitting element 40, it is possible to reduce the size of the light emitting device according to an embodiment. It is thus possible to provide a light emitting device having high luminous efficiency per area.

For example, between the first position Ps1 and the second position Ps2, two or more sections 30p maybe provided. Between the first position Ps1 and the second position Ps2, three or more semiconductor light emitting elements 40 may be provided. For example, cutting positions can be changed, whereby it is possible to manufacture light emitting devices having different sizes. It is thus possible to select the number of semiconductor light emitting elements 40 to be included in one light emitting device by varying dicing positions on the substrate 10 rather than attempting to add additional light emitting chips to the device.

As described above, the lead frames (the substrates 10) have one common design, and the resin bodies 30 have one common design. But the shapes of the first translucent portions 20 to be formed on the lead frames and the resin bodies, and the dicing positions can be changed, whereby it is possible to manufacture light emitting devices having different sizes. For example, it is possible to form various sizes of packages from one lead frame substrate, without changing the design of the frame. Also, it is possible to use a mold for forming identical resin bodies to form various sizes of packages.

For example, if a package design is changed, it may be required to newly manufacture a mold for forming resin bodies. In this case, a long period and high cost which are required to manufacture a mold for the changed package design are a heavy burden.

In contrast to this, according to the embodiment, it is possible to use the same mold for forming resin bodies, and thus it is possible to reduce the cost during development and mass production. Therefore, it is possible to provide light emitting devices having high luminous efficiency and high production efficiency.

Also, in this disclosure, it should be noted that when an element is referred to as being “perpendicular” to another element, it may be exactly perpendicular to the other element or may be substantially perpendicular to the other element, for example, due to variations in the manufacturing process.

The embodiment of the present disclosure has been described above with reference to the specific examples. However, the embodiment of the present disclosure is not limited to the specific examples. Those skilled in the art can appropriately select a specific configuration of each of the components such as the substrate, the translucent portions, the resin body, the semiconductor light emitting elements, and the wavelength conversion layers, in a known range, thereby similarly implementing the present disclosure, and these modifications are included in the scope of the present disclosure as long as it is possible to achieve the same effects as those of the present disclosure.

Further, modifications which are obtained by combining the components of two or more of the specific examples are also included in the scope of the present disclosure.

Moreover, all of light emitting devices and method of manufacturing them obtainable by appropriate design modifications by those skilled in the art based on the light emitting devices and the methods of manufacturing them described above as an embodiment of the disclosure are also included in the scope of the disclosure as long as the modifications include the gist of the present disclosure.

Various other variations and modifications can be conceived by those skilled in the art within the spirit of the disclosure, and it is understood that such variations and modifications are also encompassed within the scope of the disclosure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A light emitting device, comprising:
a first light emitting element on a substrate;
a second light emitting element on the substrate and spaced from the first light emitting;
a resin body on the substrate between the first and second light emitting elements and surrounding the first and second light emitting elements in a first plane parallel to the substrate, the resin body having a thickness in a first direction orthogonal to the substrate that is greater than a thickness in the first direction of each of the first and second light emitting elements; and
a translucent resin element on the resin body and the first and second light emitting elements, the resin body and the first and second light emitting elements being between the translucent resin element and the substrate in the first direction.

2. The light emitting device of claim 1, wherein the resin body comprises a material that reflects light at a wavelength emitted by at least one of the first and second light emitting elements.

3. The light emitting device of claim 2, wherein the material is a white resin.

4. The light emitting device of claim 2, wherein a wall of the resin body that is on a side adjacent to one of the first and second light emitting elements extends from the substrate at an oblique angle such that an interior angle between the wall of the resin body and a surface of the resin body that is facing the substrate is less than 90 degrees.

5. The light emitting device of claim 4, wherein the translucent resin element includes a single lens element having a diameter in a second plane parallel to the substrate that is greater than a distance along the substrate between first and second light emitting elements, the single lens covering the first and second light emitting elements when viewed from the first direction.

6. The light emitting device of claim 4, wherein the translucent resin element includes:
a first lens element having a diameter in a second plane parallel to the substrate that is equal to or greater than a width of the first light emitting element along the substrate and covering the first light emitting element when viewed from the first direction, and
a second lens element having a diameter in the second plane that equal to or greater than a width of the second light emitting element along the substrate and covering the second light emitting element when viewed from the first direction.

7. The light emitting device of claim 1, wherein the translucent resin element includes a single lens element having a diameter in a second plane parallel to the substrate that is greater than a distance along the substrate between first and second light emitting elements, the single lens covering the first and second light emitting elements when viewed from the first direction.

8. The light emitting device of claim 1, wherein the translucent resin element includes:
a first lens element having a diameter in a second plane parallel to the substrate that is equal to or greater than a width of the first light emitting element along the substrate and covering the first light emitting element when viewed from the first direction, and
a second lens element having a diameter in the second plane that equal to or greater than a width of the second light emitting element along the substrate and covering the second light emitting element when viewed from the first direction.

9. The light emitting device of claim 1, wherein
an anode and a cathode of the first light emitting element are on a surface of the first light emitting element that is facing in the first direction towards the translucent resin element,
an anode and a cathode of the second light emitting element are on a surface of the second light emitting element facing in the first direction towards the translucent resin element, and
the respective anodes and cathodes are connected to wiring portions on the substrate via a bond wire.

10. The light emitting device of claim 1, wherein a bonding wire extends from the first light emitting element to the second light emitting element by passing between the resin body and a portion of the translucent resin body.

11. The light emitting device of claim 1, wherein the translucent resin element is a single lens element

12. A light emitting device, comprising:
a first translucent portion on a substrate and is at least partially transparent to light at a first wavelength;
a resin body that is provided between the substrate and the first translucent portion in a first direction orthogonal to the substrate, the resin body being reflective of light at the first wavelength and having:
a first portion in contact with the first translucent portion,
a second portion separated from the first portion in a second direction intersecting the first direction and in contact with the first translucent portion, and
a third portion between the first portion and the second portion and spaced from the first and second portions in the second direction and in contact with the first translucent portion;
a first semiconductor light emitting element between the substrate and the first translucent portion in the first direction and between the first portion and the third portion in the second direction; and
a second semiconductor light emitting element between the substrate and the first translucent portion in the first direction and between the second portion and the third portion in the second direction.

13. The light emitting device according to claim 12, wherein a height of the third portion along the first direction from the substrate is greater than a height of the first semiconductor light emitting element along the first direction from the substrate.

14. The light emitting device according to claim 12, wherein a width the third portion along the second direction decreases with distance along the first direction from the substrate.

15. The light emitting device according claim 12, wherein the third portion has a sidewall that is angled with respect to the substrate in a range from 30 degrees to 90 degrees, inclusive.

16. The light emitting device according to claim 12,
the substrate having:
a first conductive portion;
a second conductive portion that is separated from the first conductive portion in the second direction; and
a third conductive portion that is separated from the first conductive portion and the second conductive portion in the second direction, wherein
at least a portion of the first semiconductor light emitting element is provided between the first conductive portion and the first translucent portion,
at least a portion of the second semiconductor light emitting element is provided between the second conductive portion and the first translucent portion, and
at least a portion of the third portion is provided between the third conductive portion and the first translucent portion.

17. The light emitting device according to claim 16, wherein
the first semiconductor light emitting element includes a first cathode and a first anode,
the second semiconductor light emitting element includes a second cathode and a second anode,
the first cathode is electrically connected to the third conductive portion, and
the second anode is electrically connected to the third conductive portion.

18. The light emitting device according to claim 12, further comprising:
a wavelength conversion layer between the first semiconductor light emitting element and the first translucent portion, wherein
the first semiconductor light emitting element emits light having a first peak wavelength, and
the wavelength conversion layer absorbs at least a portion of the light, and emits light having a second peak wavelength different from the first peak wavelength.

19. A method of manufacturing a light emitting device, comprising:
preparing a workpiece that includes:
a resin body forming a plurality of sections on a main surface of a substrate,
a plurality of light emitting elements respectively disposed on the main surface of the substrate in each section in the plurality of sections such that a portion of the resin body is between each pair of adjacent light emitting elements in the plurality of light emitting elements, and
a translucent portion disposed on the resin body and the plurality of light emitting elements; and
cutting the workpiece into separate pieces by cutting through the translucent portion, the resin body, and the substrate at a first position and a second position of the workpiece, wherein
at least one adjacent pair of light emitting elements in the plurality of light emitting elements is between the first position and the second position.

20. The method of claim 19, wherein the translucent portion comprises a plurality of lens elements respectively corresponding to each light emitting element in the plurality of light emitting elements.
